(19) United States
(12) Patent Application Publication
(10) Pub. No.: US 2005/0269673 A1
(43) Pub. Date: Dec. 8, 2005

(54) Pure copper-coated copper foil and method of producing the same, and TAB tape and method of producing the same

(75) Inventor: Akiko Sugioka, Ageo-City (JP)

Correspondence Address: ROTHWELL, FIGG, ERNST & MANBECK, P.C., 1425 K STREET, N.W., SUITE 800, WASHINGTON, DC, 20005, US

(73) Assignee: MITSUI MINING AND SMELTING CO., LTD., Tokyo (JP)

(21) Appl. No.: 11/137,799

(22) Filed: May 26, 2005

(30) Foreign Application Priority Data
May 26, 2004 (JP) 2004-156105

(51) Int. Cl. H01L 23/495; H01L 21/48

(52) U.S. Cl. 257/666; 438/123

(57) ABSTRACT

A copper foil which is substantially free of generation of voids even if fusing treatment is conducted on a tin-plated layer and which is excellent in etching properties is provided. To achieve this object, a pure copper-coated copper foil in which a pure-copper plated layer is formed at least on a gloss surface of a base copper foil is employed. The pure copper-plated layer preferably has a thickness of not less than 0.3 μm. A method of producing a pure copper-coated copper foil, in which electrolysis is conducted using, as an electrolyte, an aqueous sulfuric acid-copper sulfate solution having a Cl⁻ ion concentration of not more than 0.5 mg/l with a base copper foil serving as a cathode, thereby forming a pure copper-plated layer at least on a gloss surface of the base copper foil. The aqueous sulfuric acid-copper sulfate solution preferably has a Cu²⁺ ion concentration of 40 g/l to 120 g/l and a free SO₄²⁻ ion concentration of 100 g/l to 200 g/l.

### BACKGROUND OF THE INVENTION

1. Field of the Invention

The present invention relates to a pure copper-coated copper foil, a method of producing the same, a TAB tape and a method of producing the same, and more specifically to a pure copper-coated copper foil for producing a TAB tape, a method of producing the same, a TAB tape and a method of producing the same.

2. Description of the Related Art

TAB (Tape Automated Bonding) system is a technology intended for automation and high speeding of packaging of semiconductor devices such as ICs and LSIs. In the TAB system, specifically, a TAB tape having copper leads including inner leads and outer leads formed by etching a copper foil adhered to a long, flexible insulating film such as polyimide is used to joint pads of the substrate and pads of the above-mentioned outer leads, and pads of the above-mentioned inner leads and pads of the semiconductor device at one time, thereby jointing the substrate with the semiconductor device. In the present invention, the TAB system includes, in addition to the usual TAB system in which device holes are formed on a flexible insulating film, COF (Chip on Film) systems which are the same as the usual TAB system except that such device holes are not formed on the flexible insulating film. Accordingly, the term “TAB tape” used in the present invention includes COF tapes used in the COF system.

In the above-mentioned TAB tape, the pad of the above-mentioned inner lead and the pad of the semiconductor device, and the pad of the above-mentioned outer lead and the pad of the substrate are jointed with interposing a soldering material such as solder balls. For this reason, it is preferable that the inner lead pads and the outer lead pads have an excellent wetting ability for soldering materials, and usually, tin plating which affords an excellent wetting ability for soldering is conducted on the surface of the pads of the inner lead and the outer lead. Tin-plating also has an effect of preventing oxidization of the surface of copper which constitutes inner leads and outer leads.

However, in the tin-plated film formed on the copper lead, if no treatment is conducted, tin whisker, which is whisker-shaped needle crystal, is generated on the film surface and short-circuit is caused. Thus, tin-plated films are usually subjected to heat treatment (fusing treatment) to prepare tin-plated films free of generation of tin whisker.

When such fusing treatment is conducted, however, voids which are considered to be formed due to a Kirkendall effect tend to be generated at the interface between the copper layer and the tin-plated layer. In addition, it has been known that out of various types of low roughness foils, only certain kinds of low roughness foils are more likely to suffer from such voids, although the cause is unknown. For this reason, while such low roughness foils are sufficiently reliable and usable without any problem as a copper foil for TAB tapes having a broader circuit width as in conventional cases, they are difficult to be used as a copper foil for TAB tapes of which the circuit width has become narrower due to requirement of fine pitch as in recent cases, because of insufficient reliability of the circuit against fusing treatment.

To cope with this problem, Japanese Patent Laid-Open No. 2002-16111 discloses a copper foil used for a TAB tape which has an alloy layer comprising nickel, cobalt and molybdenum at least on the gloss surface of the copper foil. When such copper foil is used, a highly reliable TAB tape which has an effect of preventing Sn whisker and Kirkendall voids can be obtained.

However, the method described in Japanese Patent Laid-Open No. 2002-16111 had a defect that because the alloy layer comprising nickel, cobalt and molybdenum is formed on the surface of the copper foil, the alloy layer comprising these dissimilar metals deteriorates the etching properties of the copper foil in the process of forming a circuit.

Accordingly, an object of the present invention is to provide a copper foil which is substantially free of generation of voids even if fusing treatment is conducted on a tin-plated layer and which is excellent in etching properties. Another object of the present invention is to provide a TAB tape which is substantially free of generation of voids even if fusing treatment is conducted on a tin-plated layer.

### SUMMARY OF THE INVENTION

In view of such circumstances, the inventors of the present invention have conducted intensive studies and as a result have found that when a pure copper-plated layer is formed on at least a gloss surface of a copper foil, no void is substantially formed in the obtained pure copper-coated copper foil even if a tin-plated layer formed on the pure copper-plated layer is subjected to fusing treatment, and the present invention has been completed. In addition, the inventors of the present invention have found that no void is substantially formed in a TAB tape in which a pure copper-plated layer is formed on the surface of a base copper circuit formed from a base copper foil even if a tin-plated layer formed on the pure copper-plated layer is subjected to fusing treatment, and following present inventions have been completed.

The present invention provides a pure copper-coated copper foil comprising a pure copper-plated layer formed on at least a gloss surface of a base copper foil.

The pure copper-plated layer of the pure copper-coated copper foil of this invention preferably has a thickness of not less than 0.3 μm.

When producing the pure copper-coated copper foil of the present invention, the present invention provides a method of producing a pure copper-coated copper foil, comprising conducting electrolysis using, as an electrolyte, an aqueous sulfuric acid-copper sulfate solution having a Cl⁻ ion concentration of not more than 0.5 mg/l with a base copper foil serving as a cathode, thereby forming a pure copper-plated layer at least on a gloss surface of the base copper foil.

In this method of producing a pure copper-coated copper foil of the present invention, the aqueous sulfuric acid-copper sulfate solution preferably has a Cu²⁺ ion concentration of 40 g/l to 120 g/l and a free SO₄²⁻ ion concentration of 100 g/l to 200 g/l.

The present invention provides the method of producing a pure copper-coated copper foil of the present invention preferably comprising conducting electrolysis using, as an electrolyte, an aqueous sulfuric acid-copper sulfate solution having a Cl⁻ ion concentration of not more than 2.0 mg/l and a protein concentration of not more than 0.5 mg/l with a base copper foil serving as a cathode, thereby forming a pure copper-plated layer at least on a gloss surface of the base copper foil.

In this method of producing a pure copper-coated copper foil of the present invention, the aqueous sulfuric acid-copper sulfate solution preferably has a Cu²⁺ ion concentration of 40 g/l to 120 g/l and a free SO₄²⁻ ion concentration of 100 g/l to 200 g/l.

The present invention provides a TAB tape comprising a pure copper-plated layer formed on the surface of a base copper circuit formed from a base copper foil.

In this TAB tape, the pure copper-plated layer preferably has a thickness of not less than 0.3 nm.

The present invention provides the method of producing the above-mentioned TAB tape preferably comprising conducting electrolysis using, as an electrolyte, an aqueous sulfuric acid-copper sulfate solution having a Cl⁻ ion concentration of not more than 0.5 mg/l with a base copper circuit formed from a base copper foil serving as a cathode, thereby forming a pure copper-plated layer on the surface of the base copper circuit.

In this method of producing the above-mentioned TAB tape, the aqueous sulfuric acid-copper sulfate solution preferably has a Cu²⁺ ion concentration of 40 g/l to 120 g/l and a free SO₄² ion concentration of 100 g/l to 200 g/l.

The present invention provides method of producing the above-mentioned TAB tape preferably comprising conducting electrolysis using, as an electrolyte, an aqueous sulfuric acid-copper sulfate solution having a Cl⁻ ion concentration of not more than 2.0 mg/l and a protein concentration of not more than 0.5 mg/l with a base copper circuit formed from a base copper foil serving as a cathode, thereby forming a pure copper-plated layer on the surface of the base copper circuit.

In this method of producing the above-mentioned TAB tape, the aqueous sulfuric acid-copper sulfate solution has a Cu²⁺ ion concentration of 40 g/l to 120 g/l and a free SO₄₂ ion concentration of 100 g/l to 200 g/l.

The present invention provides the method of producing the above-mentioned TAB tape preferably comprising conducting electroless plating using a copper sulfate electroless plating solution having a Cu²⁺ ion concentration of 1 g/l to 5 g/l, a Cl⁻ ion concentration of not more than 0.5 mg/l and a concentration of at least one complexing agent of Rochelle salt or EDTA.4Na of 10 g/l to 100 g/l, the solution further containing formaldehyde as a reducing agent and having a pH of 10 to 13.5, thereby forming a pure copper-plated layer on the surface of a base copper circuit.

Also, the pure copper-coated copper foil of the present invention is suitable as a copper foil for producing a TAB tape because no void is substantially formed even if fusing treatment is conducted after forming a tin-plated layer since the surface on which the tin-plated layer is formed is constituted by a pure copper-plated layer. In addition, according to the method of producing a pure copper-coated copper foil of the present invention, the pure copper-coated copper foil of the present invention can be suitably produced.

Also, in the TAB tape of the present invention, no void is substantially formed even if fusing treatment is conducted after forming a tin-plated layer, because the surface on which a tin-plated layer is formed is constituted by a pure copper-plated layer. In addition, according to the method of producing a TAB tape of the present invention, the TAB tape of the present invention can be suitably produced.

### BRIEF DESCRIPTION OF THE DRAWINGS

FIG. 1 is a photograph of a cross-section of the tin-plated film-applied pure copper-coated copper foil fabricated in Example 1;

FIG. 2 is a photograph of a cross-section of the tin-plated film-applied pure copper-coated copper foil fabricated in Example 2;

FIG. 3 is a photograph of a cross-section of the tin-plated film-applied pure copper-coated copper foil fabricated in Example 3;

FIG. 4 is a photograph of a cross-section of the tin-plated film-applied pure copper-coated copper foil fabricated in Example 4; and

FIG. 5 is a photograph of a cross-section of the tin-plated film-applied copper foil fabricated in Comparative Example.

### DETAILED DESCRIPTION OF THE PREFERRED EMBODIMENTS

[Pure Copper-Coated Copper Foil of the Present Invention]

The pure copper-coated copper foil of the present invention comprises a pure copper-plated layer formed on at least a gloss surface of a base copper foil. As used herein, the base copper foil means untreated copper foil on the surface of which no pure copper-plated layer is formed. Here, the untreated copper foil means copper foil without roughening treatment such as nodular treatment or burn-plating.

Examples of untreated copper foil used in the present invention include untreated electrolytic copper foil. Although the untreated electrolytic copper foil has a defect that voids are easily generated upon fusing treatment after tin plating as compared to untreated rolled copper foil, it has an advantage that it is inexpensive and has an excellent etching properties. Therefore, when the untreated electrolytic copper foil is used as a base copper foil in the present invention where the defect of easy generation of voids is alleviated, the above-mentioned advantage of the untreated electrolytic copper foil can be suitably utilized. In particular, for forming extremely fine circuits having a pitch of about 10 μm, untreated electrolytic copper foil can be suitably used as opposed to untreated rolled copper foil which has a poor etching properties.

In addition, of the untreated electrolytic copper foils, some of the untreated low roughness electrolytic copper foils have a defect that voids are easily generated upon fusing treatment after tin plating as compared to untreated electrolytic copper foil having regular roughness. However, since such untreated electrolytic copper foil has an advantage of low surface roughness, the advantage of the untreated low roughness electrolytic copper foil can be suitably utilized when it is used as a base copper foil in the present invention where the defect of easy generation of voids is alleviated.

Further, since the finding in the process of accomplishing the present invention suggests that generation of voids can be prevented when a pure copper-plated layer having a small Cl content is formed on the surface, there is no problem of generation of voids even if the untreated electrolytic copper foil used in the present invention contains, for example, about 40 ppm or more of Cl in the copper foil based on weight, although it is basically assumed that the smaller the content of the Cl in the untreated electrolytic copper foil, the better for preventing generation of voids. In short, because the present invention can prevent the generation of voids due to fusing treatment by forming a pure copper-plated layer on the surface, the Cl concentration of the untreated electrolytic copper foil which is the base copper foil is not particularly limited. Accordingly, the present invention makes it possible to use untreated electrolytic copper foil having a high Cl content for TAB tapes, and is thus advantageous in that choices of untreated electrolytic copper foil can be flexibly extended depending on the properties, the cost, etc.

As used herein, the untreated low roughness electrolytic copper foil refers to those having a composition and a crystalline structure such that the surface roughness R_{z} of 18 μm copper foil is 3.5 μm or lower. Here, the roughness R_{z} means the ten point height of irregularities as defined in JIS B0601-1982.

Because the surface roughness R_{z} of untreated electrolytic copper foil fluctuates in substantial proportion to the thickness of the untreated electrolytic copper foil, when the untreated electrolytic copper foil is thicker than 18 μm, for example, has a thickness of 35 μm, the surface roughness R_{z} may not fall into the range of 3.5 μm or lower as described above. Even in such case, however, when electrolytic conditions other than the electrolytic time, e.g. the composition of the electrolyte and the current density, of the electrolytic conditions of the untreated electrolytic copper foil, are the same, compositions and crystalline structures of the untreated electrolytic copper foils themselves are substantially the same regardless of the difference in the thickness of the electrolytic copper foils. In the present invention, therefore, such foils are also regarded as untreated low roughness electrolytic copper foil.

The pure copper-coated copper foil of the present invention has a pure copper-plated layer formed at least on a gloss surface of a base copper foil. As used herein, the pure copper-plated layer means a copper layer which contains substantially no metal component other than Cu and in which the content of Cl in the pure copper-plated layer is usually not more than 30 ppm, preferably not more than 20 ppm, and more preferably not more than 10 ppm based on weight. In the present invention, when the pure copper-plated layer is formed so that it contains substantially no metal component other than Cu and has a Cl content in the above-mentioned range, voids due to fusing treatment become difficult to be generated. The pure copper-plated layer may contain metal components other than Cu and/or elements other than Cl, e.g. C, N, etc. in an amount of usually not more than 200 ppm, preferably not more than 100 ppm, and more preferably not more than 50 ppm based on weight of the total contents of the elements.

The pure copper-plated layer is formed at least on a gloss surface of a base copper foil. More specifically, the pure copper-plated layer may be formed only on a gloss surface of the base copper foil or on a rough face in addition to the gloss surfaces. In the present invention, the reason for forming the pure copper-plated layer at least on a gloss surface of the base copper foil is because a tin-plated film formed on inner leads and outer leads of a TAB tape is generally formed on the gloss surface of the base copper foil which is a material of the inner leads and the outer leads.

In the pure copper-coated copper foil of the present invention, the thickness of the pure copper-plated layer cannot be simply determined because decrease in the thickness of the pure copper-plated layer due to etching upon fabrication of a TAB tape must be considered, but when there is no substantial decrease in the thickness of the pure copper-plated layer due to etching, the thickness is usually not less than 0.3 μm, preferably 0.3 μm to 25 μm, and more preferably 0.7 μm to 2.0 μm.

A thickness of the pure copper-plated layer of less than 0.3 μm is not preferable because generation of voids after fusing treatment cannot be sufficiently prevented. A pure copper-plated layer thicker than needed is not preferable because the production cost is increased while the effect of preventing generation of voids after fusing treatment does not increase. For example, when the thickness of the pure copper-plated layer is more than 25 μm, it tends to be difficult to correspond to fabrication of minute circuits.

When the thickness of the pure copper-plated layer on the surface of the pure copper-coated copper foil is decreased due to etching upon fabrication of a TAB tape, the thickness of the pure copper-plated layer of the pure copper-coated copper foil of the present invention is defined to be the sum of the decreased amount of the pure copper-plated layer and the thickness of the pure copper-plated layer. For example, when the decreased amount of the pure copper-plated layer due to etching upon fabrication of a TAB tape is 0.5 μm, the thickness of the pure copper-plated layer of the pure copper-coated copper foil of the present invention is usually not less than 0.8 μm, preferably 0.8 μm to 25.5 μm, and more preferably 1.2 μm to 2.5 μm.

Where necessary, for the pure copper-coated copper foil of the present invention, rust proofing treatment may be conducted on one or both of the surface of the pure copper-plated layer and the surface of the base copper foil on which the pure copper-plated layer is not formed. When such rust proofing treatment is conducted, the rust proofing properties from the step of the production of the pure copper-coated copper foil to the step of adhesion of the foil to a flexible insulating film such as polyimide of a TAB tape are preferably improved. However, when the rust proofing treatment is conducted on the surface of the pure copper-plated layer, the rust proofing layer formed by the rust proofing treatment must have a composition and a thickness which do not affect tin plating conducted on the surface of the pure copper-plated layer when producing a TAB tape.

As such rust proofing treatment, one or both of inorganic rust proofing treatment and organic rust proofing treatment may be conducted. Examples of inorganic rust proofing treatment include metal rust proofing treatment using at least one metal element such as zinc, nickel and tin and chromate treatment.

When two or more of metal elements such as zinc, nickel and tin are combined in the metal rust proofing treatment, the metal rust proofing layer formed by the metal rust proofing treatment may have a multi-layer structure with a plurality of metal rust proofing layers each made of a metal element, or may have a single layer structure by forming into an alloy by heat treatment when forming a rust proofing layer or after forming rust proofing layers of a multi-layer structure. In addition, in the inorganic rust proofing treatment, chromate treatment after metal rust proofing treatment is preferable because the rust proofing properties of the rust proofing layer can be further improved.

The organic rust proofing treatment for forming an organic rust proofing layer includes, for example, a silane coupling agent and benzotriazole. When the inorganic rust proofing treatment and the organic rust proofing treatment are conducted in combination, an organic rust proofing layer is preferably formed after forming an inorganic rust proofing layer. For the above-mentioned inorganic and organic treatment, known methods can be used. The pure copper-coated copper foil of the present invention may be produced by the method of producing a pure copper-coated copper foil of the present invention described below, for example.

[Method of Producing Pure Copper-Coated Copper Foil of the Present Invention]

The method of producing a pure copper-coated copper foil of the present invention includes a first method which comprises conducting electrolysis using, as an electrolyte, an aqueous sulfuric acid-copper sulfate solution which contains substantially no Cl⁻ ion (hereinafter also referred to as a first aqueous sulfuric acid-copper sulfate solution) with a base copper foil serving as a cathode, thereby forming a pure copper-plated layer at least on a gloss surface of the base copper foil (hereinafter also referred to as a first method of producing copper foil); and a second method which comprises conducting electrolysis using, as an electrolyte, an aqueous sulfuric acid-copper sulfate solution of which the Cl⁻ ion concentration is not more than a specific level and which contains substantially no protein (hereinafter also referred to as a second aqueous sulfuric acid-copper sulfate solution) with a base copper foil serving as a cathode, thereby forming a pure copper-plated layer at least on a gloss surface of the base copper foil (hereinafter also referred to as a second method of producing copper foil).

(First Method of Producing Copper Foil)

The first method of producing copper foil is now described. The first aqueous sulfuric acid-copper sulfate solution used as an electrolyte in this method contains, as ions, substantially only Cu²⁺ and SO₄²⁻, and substantially no Cl⁻ ion. Here, the first aqueous sulfuric acid-copper sulfate solution used in the present invention “containing substantially no Cl⁻ ion” means that the Cl⁻ ion concentration in the first aqueous sulfuric acid-copper sulfate solution is not more than 0.5 mg/l, preferably not more than 0.3 mg/l, and more preferably not more than 0.1 mg/l. A Cl⁻ ion concentration of more than 0.5 mg/l is not preferable because it becomes difficult for the pure copper-plated layer formed by electrolysis to sufficiently exhibit the effect of preventing generation of voids.

The first aqueous sulfuric acid-copper sulfate solution may contain additives other than the above-mentioned Cu²⁺, SO₄²⁻ and Cl⁻ ions. Examples of such additives include organic substances such as protein. Examples of protein include gelatin and glue. When the additive is protein, the first aqueous sulfuric acid-copper sulfate solution may contain the protein in the range of usually not more than 5 mg/l, and preferably not more than 3 mg/l. A content of protein of more than 5 mg/l is not preferable because the pure copper-plated layer tends to be harder and more brittle.

The first aqueous sulfuric acid-copper sulfate solution used in the present invention has a Cu²⁺ ion concentration of usually 40 g/l to 120 g/l, and preferably 60 g/l to 100 g/l. A Cu²⁺ ion concentration of less than 40 g/l is not preferable because burn-plating tends to occur even if electrolysis is conducted, making it difficult to form a fine copper layer. A Cu²⁺ ion concentration of more than 120 g/l is not preferable because crystal of copper sulfate tends to precipitate easily.

The first aqueous sulfuric acid-copper sulfate solution used in the present invention has a free SO₄²⁻ ion concentration of usually 100 g/l to 200 g/l, and preferably 120 g/l to 180 g/l. Here, the free SO₄²⁻ concentration refers to remaining SO₄²⁻ concentration found by subtracting the SO₄²⁻ concentration obtained by converting the Cu²⁺ concentration in the first aqueous sulfuric acid-copper sulfate solution to CuSO₄ from the total SO₄²⁻ concentration in the first aqueous sulfuric acid-copper sulfate solution. A free SO₄²⁻ concentration of less than 100 g/l is not preferable because the solution resistance is increased. A free SO₄²⁻ concentration of more than 200 g/l is not preferable because abnormal deposition tends to occur in the pure copper-plated layer.

The first aqueous sulfuric acid-copper sulfate solution used in the present invention is obtained by, for example, adding sulfuric acid to pure water and then dissolving sulfuric copper, or by dissolving a copper raw material such as copper scrap with diluted sulfuric acid or the first aqueous sulfuric acid-copper sulfate solution.

In the first method of producing copper foil, a pure copper-plated layer is formed at least on a gloss surface of base copper foil using the above-mentioned first aqueous sulfuric acid-copper sulfate solution as an electrolyte with the base copper foil serving as a cathode. Since the base copper foil used in the method of producing a pure copper-coated copper foil of the present invention is the same as the base copper foil described in the explanation of the pure copper-coated copper foil of the present invention, description thereof is omitted. As a method of electrolysis in which base copper foil serves as a cathode, known methods may be employed and for example, a method of electrolysis in which an anode is placed in the first aqueous sulfuric acid-copper sulfate solution and a feed roll is used for the base copper foil to conduct feeding so that the base copper foil itself serves as a cathode; and a method may be used in which an anode is placed on one side of the base copper foil at a pre-determined distance while a cathode is placed on the other side of the base copper foil at a pre-determined distance in the first aqueous sulfuric acid-copper sulfate solution, so as to feed electric current to the base copper foil, sandwiching the base copper foil between the anode and the cathode in such a way that the base copper foil in itself serves as a cathode.

When conducting electrolysis using the above-mentioned first aqueous sulfuric acid-copper sulfate solution, the temperature of the above-mentioned first aqueous sulfuric acid-copper sulfate solution is usually 40° C. to 60° C., and preferably 45° C. to 55° C. A temperature of the solution of lower than 40° C. is not preferable because the surface roughness of the pure copper-plated layer is easily increased. A temperature of the solution of higher than 60° C. is not preferable because it easily accelerates deterioration of equipment such as vinyl chloride piping.

When conducting electrolysis using the above-mentioned first aqueous sulfuric acid-copper sulfate solution, the current density for electrolysis is usually 40 A/dm² to 70 A/dm², and preferably 50 A/dm² to 60 A/dm². A current density for electrolysis of less than 40 A/dm² is not preferable because the deposition speed is too low and the production cost of the pure copper-coated copper foil tends to increase. A current density for electrolysis of more than 70 A/dm² is not preferable because abnormal deposition tends to occur in the pure copper-plated layer.

(Second Method of Producing Copper Foil)

Next, the second method of producing copper foil is described. In this method, conditions and the grounds for specifying the conditions are the same as those in the first method of producing copper foil except that a second aqueous sulfuric acid-copper sulfate solution is used in place of the above-mentioned first aqueous sulfuric acid-copper sulfate solution. The second aqueous sulfuric acid-copper sulfate solution has a Cl⁻ ion concentration of not more than 2.0 mg/l, and preferably not more than 1.0 mg/l. A Cl⁻ ion concentration of more than 2.0 mg/l is not preferable because it becomes difficult for the pure copper-plated layer formed by electrolysis to sufficiently exhibit the effect of preventing generation of voids.

The second aqueous sulfuric acid-copper sulfate solution contains substantially no protein, and has a protein concentration of not more than 0.5 mg/l, and preferably not more than 0.3 mg/l. A protein concentration of more than 0.5 mg/l is not preferable because it becomes difficult for the pure copper-plated layer formed by electrolysis to sufficiently exhibit the effect of preventing generation of voids.

The pure copper-coated copper foil of the present invention and the method of producing a pure copper-coated copper foil of the present invention can be employed for copper foil raw materials for fabricating TAB tapes.

[TAB Tape of the Present Invention]

The TAB tape of the present invention comprises a copper-coated circuit which has a pure copper-plated layer on the surface of a base copper circuit, with the pure copper-plated layer being formed on the surface of the base copper circuit formed from a base copper foil. In the present invention, the TAB tape includes both usual TAB tapes in which device holes are formed on a flexible insulating film and so-called COF tapes in which device holes are not formed thereon as described above. The TAB tape used in the present invention includes, for example, a three layer TAB tape having a three layer structure of flexible insulating film/adhesive/copper-coated circuit and a two layer TAB tape having a two layer structure of flexible insulating film/copper-coated circuit.

In the TAB tape of the present invention, the copper-coated circuit has a pure copper-plated layer formed on the base copper circuit. The base copper circuit, which is described below, is shaped into a circuit by etching a base copper foil adhered to a flexible insulating film. As the base copper foil used in the present invention, untreated copper foil similar to those described in the explanation of the pure copper-coated copper foil of the present invention may be used. The base copper circuit is a circuit formed from a base copper foil by etching.

In the TAB tape of the present invention, a copper-coated circuit is obtained by forming a pure copper-plated layer on the entire surface of the base copper circuit. In the copper-coated circuit, the cross-section perpendicular to the direction of the current flow of the circuit has a double structure of a base copper circuit and a pure copper-plated layer surrounding the same. The pure copper-plated layer is interposed between the base copper circuit and a tin-plated layer, thereby preventing the contact between the base copper circuit and the tin-plated layer.

In the TAB tape of the present invention, the thickness of the pure copper-plated layer is in the same range as the thickness of the pure copper-plated layer of the pure copper-coated copper foil of the present invention. In this regard, the thickness of the pure copper-plated layer in the TAB tape of the present invention means an average thickness of the pure copper-plated layer. The pure copper-plated layer is formed on the all surfaces of a base copper circuit. Thus, of the three or four surfaces of the base copper circuit which has a substantially rectangular cross-section, i.e., of the one or two surfaces of the surfaces of the base copper circuit surfaces roughly parallel to the flexible insulating film and two surfaces of the base copper circuit surfaces roughly perpendicular to the flexible insulating film, when the pure copper-plated layer on the latter surfaces is too thick, short-circuit of adjacent copper-coated circuits may be caused. For this reason, the thickness of the pure copper-plated layer needs to be designed to allow adjacent copper-coated circuits to have a distance which causes no short-circuit between them. It should be noted that the number of the former surfaces roughly parallel to the flexible insulating film is one or two because it is one at the part where the base copper circuit is formed on the surface of the flexible insulating film, while two surfaces are formed, i.e., one on the top and the other at the bottom of the base copper circuit, when the base copper circuit is an inner lead formed on a device hole as a flying lead.

The distance for not causing the short-circuit between the copper-coated circuits cannot be simply determined because it varies depending on the thickness of the copper-coated circuit, but the distance is usually not less than 5 μm, preferably not less than 10 μm. For determining the upper limit of the thickness of the pure copper-plated layer, for example, when base copper circuits having a line width of 15 μm are formed at a pitch of 30 μm, the distance between the adjacent base copper circuits is 15 μm, and to maintain a distance for not causing short-circuit between the copper-coated circuits of not less than 5 μm, the line width of the copper-coated circuit is set to less than 25 μm by adjusting the thickness of the pure copper-plated layer formed on the base copper circuit to less than 5 μm.

A tin-plated layer is formed on the surface of the copper-coated circuit obtained by forming a pure copper-plated layer on the surface of the base copper circuit. The tin-plated layer is subjected to heating treatment (fusing treatment) for preventing generation of tin whisker. As the conditions of the fusing treatment, known methods may be used. Upon the fusing treatment, all or part of the tin in the tin-plated layer is fused with the copper in the pure copper-plated layer to form an alloy, and all or part of the tin-plated layer forms a Cu₆Sn₅ layer or a Cu₃Sn layer. In the present invention, the tin-plated layer is not necessarily of a single layer structure, but may be, for example, of a two layer structure of a Cu₆Sn₅ layer and a Cu₃Sn layer. The thickness of the tin-plated layer of the TAB tape of the present invention is not particularly limited. The TAB tape of the present invention can be obtained, for example, by the method of producing a TAB tape of the present invention described below.

[Method of Producing TAB Tape of the Present Invention]

The method of producing a TAB tape of the present invention includes a first method which comprises conducting electrolysis using, as an electrolyte, an aqueous sulfuric acid-copper sulfate solution of which the Cl⁻ ion concentration is within a specific range (hereinafter also referred to as a first aqueous sulfuric acid-copper sulfate solution) with a base copper circuit formed from a base copper foil serving as a cathode, thereby forming a pure copper-plated layer on the surface of the base copper circuit (hereinafter also referred to as a first method of producing a TAB tape); a second method which comprises conducting electrolysis using, as an electrolyte, an aqueous sulfuric acid-copper sulfate solution of which the Cl⁻ ion concentration and the protein concentration are within specific ranges (hereinafter also referred to as a second aqueous sulfuric acid-copper sulfate solution) with a base copper circuit formed from a base copper foil serving as a cathode, thereby forming a pure copper-plated layer on the surface of the base copper circuit (hereinafter also referred to as a second method of producing a TAB tape); and a third method which comprises conducting electroless plating using a copper sulfate electroless plating solution of which the Cu²⁺ ion concentration, the Cl⁻ ion concentration, the concentration of a complexing agent and the pH are within specific ranges, and which contains a reducing agent, thereby forming a pure copper-plated layer on the surface of a base copper circuit formed from a base copper foil (hereinafter also referred to as a third method of producing a TAB tape).

(First Method of Producing TAB Tape)

The first method of producing a TAB tape is now described. In this method, the same first aqueous sulfuric acid-copper sulfate solution as described in the first method of producing copper foil is used as an electrolyte.

In this method, electrolysis is conducted using the first aqueous sulfuric acid-copper sulfate solution with a base copper circuit formed from a base copper foil serving as a cathode, thereby forming a pure copper-plated layer on the surface of the base copper circuit. Since the base copper foil used in the first method of producing a TAB tape is the same as the base copper foil described in the first method of producing copper foil, description thereof is omitted. The base copper circuit according to the present invention is shaped into a circuit by etching a base copper foil adhered to a flexible insulating film. As such etching method, known methods can be employed.

In this method, as a method of electrolysis in which the base copper circuit serves as a cathode, known methods may be employed and for example, a method of electrolysis in which an anode is placed in the first aqueous sulfuric acid-copper sulfate solution and a feed roll is used for the base copper circuit so that the base copper circuit itself serves as a cathode. Since the temperature of the first aqueous sulfuric acid-copper sulfate solution and the current density for electrolysis when conducting electrolysis using the above-mentioned first aqueous sulfuric acid-copper sulfate solution are the same as those in the first method of producing copper foil, description thereof is omitted.

(Second Method of Producing TAB Tape)

Next, the second method of producing a TAB tape is described. In this method, conditions and the grounds for specifying the conditions are the same as those in the first method of producing a TAB tape except that a second aqueous sulfuric acid-copper sulfate solution is used in place of the above-mentioned first aqueous sulfuric acid-copper sulfate solution. As such second aqueous sulfuric acid-copper sulfate solution, the same second aqueous sulfuric acid-copper sulfate solution as described in the second method of producing copper foil is used.

(Third Method of Producing TAB Tape) Next, the third method of producing a TAB tape is described. In this method, electroless plating is conducted using a copper sulfate electroless plating solution of which the Cu²⁺ ion concentration, the Cl⁻ ion concentration, the concentration of a complexing agent and the pH are within specific ranges, and which contains a reducing agent, thereby forming a pure copper-plated layer on the surface of a base copper circuit formed from a base copper foil.

The copper sulfate electroless plating solution has a Cu²⁺ ion concentration of 1 g/l to 5 g/l, preferably 2 g/l to 4 g/l. The copper sulfate electroless plating solution contains substantially no free SO₄² ion unlike the above-mentioned first aqueous sulfuric acid-copper sulfate solution.

The copper sulfate electroless plating solution has a Cl⁻ ion concentration of not more than 0.5 mg/l, preferably not more than 0.3 mg/l, more preferably not more than 0.1 mg/l. A Cl⁻ ion concentration of more than 0.5 mg/l is not preferable because it becomes difficult for the pure copper-plated layer to sufficiently exhibit the effect of preventing generation of voids.

Examples of complexing agent used for the copper sulfate electroless plating solution include at least one member of Rochelle salt or EDTA.4Na. In other words, as the complexing agent, either Rochelle salt or EDTA.4Na may be used alone or Rochelle salt and EDTA.4Na may be used in combination.

The copper sulfate electroless plating solution contains such complexing agent in a proportion of 10 g/l to 100 g/l, preferably 30 g/l to 70 g/l. In the present invention, when the two, i.e., Rochelle salt and EDTA.4Na, are used together as complexing agents, the concentration of the total amount is supposed to be within the above-mentioned range.

The reducing agent used for the copper sulfate electroless plating solution includes, for example, formaldehyde. When the reducing agent is formaldehyde, the copper sulfate electroless plating solution contains formaldehyde in a proportion of usually 5 ml/l to 100 ml/l, preferably 30 ml/l to 70 ml/l as converted to a 37% v/v aqueous formaldehyde solution.

The copper sulfate electroless plating solution may contain an additive such as polyethylene glycol or bipyridyl where necessary. The pH of the copper sulfate electroless plating solution is pH 10 to 13.5, preferably pH 11 to 13.

When the copper sulfate electroless plating solution has a Cu²⁺ ion concentration, a Cl⁻ ion concentration and a content of the complexing agent of the above-mentioned range, and contains a reducing agent and has a pH of the above-mentioned range, a smooth pure copper-plated layer can be formed on the surface of the base copper circuit.

In this method, as a method of forming a pure copper-plated layer on the surface of a base copper circuit using the above-mentioned copper sulfate electroless plating solution, known methods may be employed.

The TAB tape of the present invention can be used as a TAB tape as is or after being processed accordingly. The method of producing a TAB tape of the present invention can be used for fabrication of TAB tapes.

Hereinafter, Examples are described, but the present invention is not to be construed as limited to these Examples.

### EXAMPLE 1

As an electrolyzer for forming a pure copper-plated layer on a base copper foil, one with the following specification was used in which the cross-section of the channel between the anode and the cathode is rectangular and which is capable of conducting electrolysis with continuously supplying an aqueous sulfuric acid-copper sulfate solution (electrolyte) between the anode and the cathode using a circulating pump.
Amount of solution in bath: 4.5 l
Size of anode surface and cathode surface: 6 cm×11 cm
Material of anode: DSE
Material of cathode: titanium plate
Distance between anode and cathode: 5 mm

For an aqueous sulfuric acid-copper sulfate solution, sulfuric acid and copper sulfate 5-hydrate were added to and dissolved in pure water to prepare a solution having the following composition.
Cu²⁺ concentration: 80 g/l
free SO₄²⁻ concentration: 150 g/l

Base copper foil having a Cl content of 40 ppm based on weight (thickness: 18 μm, ten point height of irregularities R_{z} of gloss surface: 0.8 μm, R_{z} of roughened surface: 3.0 μm, content of C in foil based on weight: 40 ppm) was acid-cleaned by 2N—H₂SO₄ at 25° C. for 30 seconds and adhered to the cathode surface so that the gloss surface is on the top. Electrolysis was conducted under the following conditions to form a pure copper-plated layer having a thickness of 0.75 μm on the gloss surface of the base copper foil, and a pure copper-coated copper foil was obtained.
Temperature of copper electrolyte: 52° C.
Current density for electrolysis: 55 A/dm²
Time of electrolysis: 4 seconds

Using TIMPOSIT XP-LT34G made by Shipley Far East Ltd., electroless tin plating was conducted on the surface of the obtained pure copper-coated copper foil (on the gloss surface of the base copper foil) to form a tin-plated film having a thickness of 0.5 μm.

The pure copper-coated copper foil on which a tin-plated film was formed (tin-plated film-applied pure copper-coated copper foil) was heated at 160° C. for 1 hour, and further heated at 120° C. for 1 hour (fusing treatment).

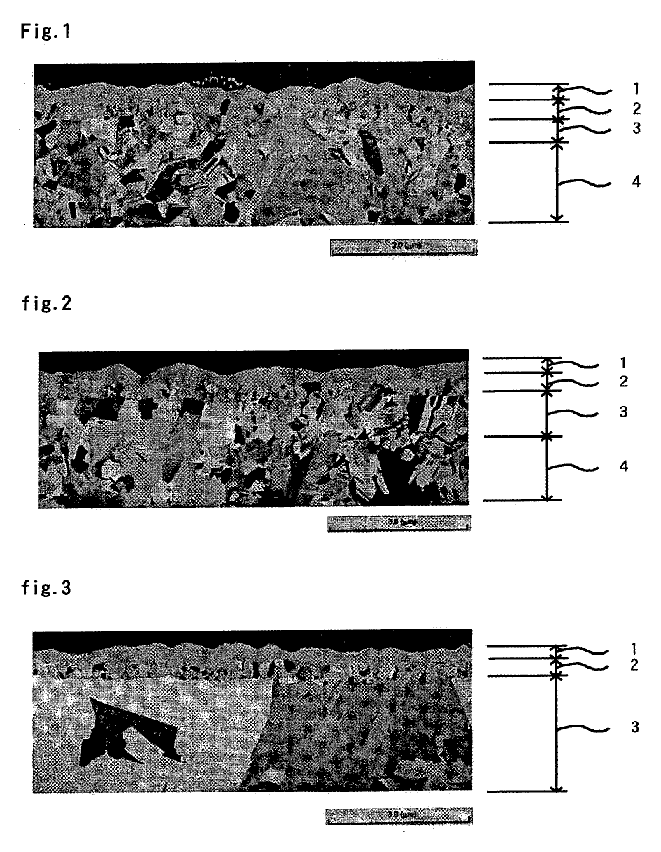

A sample for cross-sectional observation was prepared from the tin-plated film-applied pure copper-coated copper foil after the fusing treatment using a focused ion beam (FIB) apparatus, and secondary electron emission at that time was observed using a scanning ion microscope (SIM). The result is shown in FIG. 1.

In FIG. 1, from the top in the figure, observed are a tin-plated layer (Cu₆Sn₅ layer) (1) which appears entirely uniformly gray in the picture, a tin-plated layer (Cu₃Sn layer) (2) which is located under the tin-plated layer (Cu₆Sn₅ layer) (1) and has a metal structure grown like a column, a pure copper-plated layer (3) which is located under the tin-plated layer (Cu₃Sn layer) (2) and has a metal structure larger than the columnar metal structure of the tin-plated layer (Cu₃Sn layer) (2) and grown in random directions, and a base copper foil layer (4) which is located under the pure copper-plated layer (3) and has a metal structure as large and grown in random directions as the metal structure of the pure copper-plated layer (3).

FIG. 1 shows that voids (5) as found in the Comparative Example described below are not observed near the interface between the tin-plated layer (Cu₃Sn layer) (2) and the pure copper-plated layer (3).

In FIG. 1, the interface between the pure copper-plated layer (3) and the base copper foil layer (4) was not observed as clearly as other interfaces, for example, the interface between the tin-plated layer (Cu₃Sn layer) (2) and the pure copper-plated layer (3). However, from the fact that the thickness calculated from the current density for electrolysis and the time of electrolysis is 0.75 μm and that discontinuity of structure which may be an interface is occasionally found at a position about 0.75 μm below the interface between the tin-plated layer (Cu₃Sn layer) (2) and the pure copper-plated layer (3) in a direction substantially perpendicular to the grow direction of the metal structure of copper, i.e., in the crosswise direction in FIG. 1, the presence of the interface between the pure copper-plated layer (3) and the base copper foil layer (4) can be inferred.

### EXAMPLE 2

A tin-plated film-applied pure copper-coated copper foil after fusing treatment was prepared in the same manner as in Example 1 except that the time of electrolysis was 8 seconds and the thickness of the pure copper-plated layer to be formed was 1.5 μm.

The metal structure of the cross-section of the tin-plated film-applied pure copper-coated copper foil after fusing treatment was observed as in Example 1. The result is shown in FIG. 2.

In FIG. 2, from the top in the figure, observed are a tin-plated layer (Cu₆Sn₅ layer) (1) which appears entirely uniformly gray in the picture, a tin-plated layer (Cu₃Sn layer) (2) which is located under the gray tin-plated layer (Cu₆Sn₅ layer) (1) and has a metal structure grown like a column, a pure copper-plated layer (3) which is located under the tin-plated layer (Cu₃Sn layer) (2) and has a metal structure slightly larger than the columnar metal structure of the tin-plated layer (Cu₃Sn layer) (2) and grown in random directions, and a base copper foil layer (4) which is located under the pure copper-plated layer (3) and has a metal structure as large as the metal structure of the pure copper-plated layer (3) and grown in quite random directions.

FIG. 2 shows that voids (5) as found in the Comparative Example described below are not observed near the interface between the tin-plated layer (Cu₃Sn layer) (2) and the pure copper-plated layer (3).

### EXAMPLE 3

A tin-plated film-applied pure copper-coated copper foil after fusing treatment was prepared in the same manner as in Example 1 except that the time of electrolysis was 30 seconds and the thickness of the pure copper-plated layer to be formed was 5.7 μm.

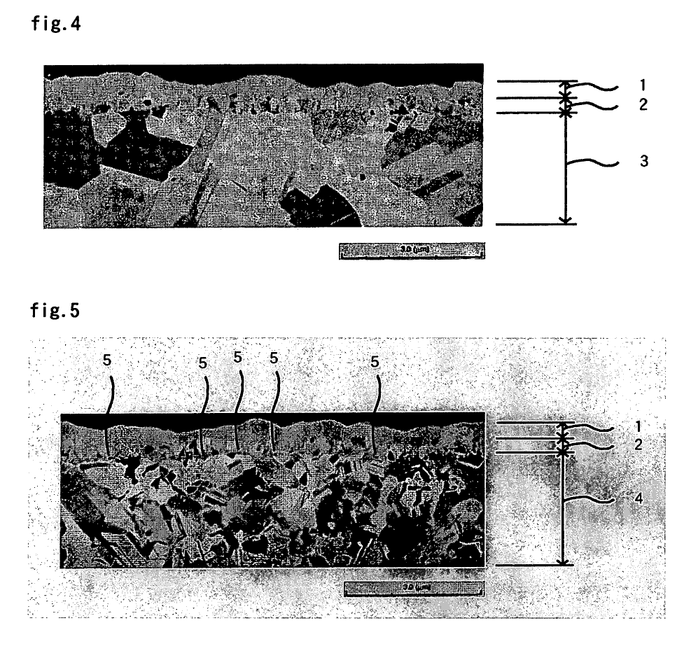

The metal structure of the cross-section of the tin-plated film-applied pure copper-coated copper foil after fusing treatment was observed as in Example 1. The result is shown in FIG. 3.

In FIG. 3, from the top in the figure, observed are a tin-plated layer (Cu₆Sn₅ layer) (1) which appears entirely uniformly gray in the picture, a tin-plated layer (Cu₃Sn layer) (2) which is located under the gray tin-plated layer (Cu₆Sn₅ layer) (1) and has a metal structure grown like a column, a pure copper-plated layer (3) which is located under the tin-plated layer (Cu₃Sn layer) (2) and has a metal structure considerably larger than the columnar metal structure of the tin-plated layer (Cu₃Sn layer) (2) and grown in random directions. While a base copper foil layer (4) which has a metal structure as large as the metal structure of the pure copper-plated layer (3) and grown in quite random directions was observed under the pure copper-plated layer (3), it is not seen in FIG. 3 in which only surface layers were photographed, because the pure copper-plated layer (3) is as thick as 5.7 μm.

FIG. 3 shows that voids (5) as found in the Comparative Example described below are not observed near the interface between the tin-plated layer (Cu₃Sn layer) (2) and the pure copper-plated layer (3).

### EXAMPLE 4

A tin-plated film-applied pure copper-coated copper foil after fusing treatment was prepared in the same manner as in Example 1 except that the time of electrolysis was 30 seconds and the thickness of the pure copper-plated layer to be formed was 22.5 μm.

The metal structure of the cross-section of the tin-plated film-applied pure copper-coated copper foil after fusing treatment was observed as in Example 1. The result is shown in FIG. 4.

In FIG. 4, from the top in the figure, observed are a tin-plated layer (Cu₆Sn₅ layer) (1) which appears entirely uniformly gray in the picture, a tin-plated layer (Cu₃Sn layer) (2) which is located under the gray tin-plated layer (Cu₆Sn₅ layer) (1) and has a metal structure grown like a column, a pure copper-plated layer (3) which is located under the tin-plated layer (Cu₃Sn layer) (2) and has a metal structure considerably larger than the columnar metal structure of the tin-plated layer (Cu₃Sn layer) (2) and grown in random directions. While a base copper foil layer (4) which has a metal structure as large as the metal structure of the pure copper-plated layer (3) and grown in quite random directions was observed under the pure copper-plated layer (3), it is not seen in FIG. 4 in which only surface layers were photographed, because the pure copper-plated layer (3) is as thick as 22.5 μm.

FIG. 4 shows that voids (5) as found in the Comparative Example described below are not observed near the interface between the tin-plated layer (Cu₃Sn layer) (2) and the pure copper-plated layer (3).

### COMPARATIVE EXAMPLE

A tin-plated film-applied copper foil after fusing treatment was prepared in the same manner as in Example 1 except that a tin-plated film having a thickness of 0.5 μm was formed by conducting electroless tin plating directly on the surface of the base copper foil (the gloss surface of the base copper foil) without forming a pure copper-plated layer.

The metal structure of the cross-section of the tin-plated film-applied copper foil after fusing treatment was observed as in Example 1. The result is shown in FIG. 5.

In FIG. 5, from the top in the figure, observed are a tin-plated layer (Cu₆Sn₅ layer) (1) which appears entirely uniformly gray in the picture, a tin-plated layer (Cu₃Sn layer) (2) which is located under the gray tin-plated layer (Cu₆Sn₅ layer) (1) and has a metal structure grown like a column, a base copper foil layer (4) which is located under the tin-plated layer (Cu₃Sn layer) (2) and has a metal structure larger than the columnar metal structure of the tin-plated layer (Cu₃Sn layer) (2) and grown in quite random directions.

FIG. 5 shows that many voids (5) were generated near the interface between the tin-plated layer (Cu₃Sn layer) (2) and the base copper foil layer (4).

Examples 1 to 4 and Comparative Example show that when no pure copper-plated layer (3) is formed as in conventional products (Comparative Example), many voids are found near the interface between the tin-plated layer (Cu₃Sn layer) (2) and the base copper foil layer (4), whereas when a pure copper-plated layer (3) is formed between the tin-plated layer (Cu₃Sn layer) (2) and the base copper foil layer (4) (Examples 1 to 4) as in the present invention, generation of voids after fusing treatment can be prevented.

The pure copper-coated copper foil of the present invention can be used as a pure copper-coated copper foil for producing a TAB tape, for example. The method of producing a pure copper-coated copper foil of the present invention can be used for producing the pure copper-coated copper foil of the present invention. The TAB tape of the present invention can be used as a TAB tape as is or after being processed appropriately. The method of producing a TAB tape of the present invention can be used for producing the TAB tape of the present invention.

1-13. (canceled)

14. A pure copper-coated copper foil comprising a base copper foil having a gloss surface and a pure copper-plated layer formed on at least the gloss surface.

15. The pure copper-coated foil according to claim 14, wherein the pure copper-plated layer has a thickness of not less than 0.3 μm.

16. A method of producing a pure copper-coated copper foil according to claim 14, which comprises forming a pure copper-plated layer at least on the gloss surface of the base copper foil by conducting electrolysis using, as an electrolyte, and aqueous sulfuric acid-copper sulfate solution having a Cl⁻ ion concentration of not more than 0.5 mg/1 with the base copper foil serving as a cathode.

17. The method of producing a pure copper-coated copper foil according to claim 16, wherein the aqueous sulfuric acid-copper sulfate solution has a Cu²⁺ ion concentration of 40 g/l to 120 g/l and a free SO₄² ion concentration of 100 g/l to 200 g/l.

18. A method of producing a pure copper-coated copper foil according to claim 14, which comprises forming a pure copper-plated layer at least on the gloss surface of the base copper foil conducting electrolysis using, as an electrolyte, an aqueous sulfuric acid-copper sulfate solution having a Cl⁻ ion concentration of not more than 2.0 mg/1 and a protein concentration of not more than 0.5 mg/1 with the base copper foil serving as a cathode.

19. The method of producing a pure copper-coated copper foil according to claim 18, wherein the aqueous sulfuric acid-copper sulfate solution has a Cu²⁺ ion concentration of 40 g/l to 120 g/l and a free SO₄² ion concentration of 100 g/l to 200 g/l.

20. A TAB tape comprising a pure copper-plated layer formed on a surface of a base copper circuit formed from a base copper foil.

21. The TAB tape according to claim 20, wherein the pure copper-plated layer has a thickness of not less than 0.3 μm.

22. A method of producing a TAB tape according to claim 20, which comprises forming a pure copper-plated layer on the surface of the base copper circuit conducting electrolysis using, as an electrolyte, an aqueous sulfuric acid-copper sulfate solution having a Cl⁻ ion concentration of not more than 0.5 mg/1 with the base copper circuit formed from the base copper foil serving as a cathode.

23. The method of producing a TAB tape according to claim 22, wherein the aqueous sulfuric acid-copper sulfate solution has a Cu²⁺ ion concentration of 40 g/l to 120 g/l and a free SO₄²⁻ ion concentration of 100 g/l to 200 g/l.

24. A method of producing a TAB tape according to claim 20, which comprises by forming a pure copper-plated layer on the surface of the base copper circuit conducting electrolysis using, as an electrolyte, an aqueous sulfuric acid-copper sulfate solution having a Cl⁻ ion concentration of not more than 2.0 mg/1 and a protein concentration of not more than 0.5 mg/1 with the base copper circuit formed from the base copper foil serving as a cathode.

25. The method of producing a TAB tape according to claim 24, wherein the aqueous sulfuric acid-copper sulfate solution has a Cu²⁺ ion concentration of 40 g/l to 120 g/l and a free SO₄²⁻ ion concentration of 100 g/l to 200 g/l.

26. A method of producing a TAB tape according to claim 20, which comprises by forming the pure copper-plated layer on the surface of the base copper circuit formed from the base copper foil conducting electroless plating using a copper sulfate electroless plating solution having a Cu²⁺ ion concentration of 1 g/l to 5 g/l, a Cl⁻ ion concentration of not more than 0.5 mg/1 and a concentration of at least one complexing agent which is Rochelle salt or EDTA 4Na of 10 g/l to 100 g/l, the solution further containing formaldehyde as a reducing agent and having a pH of 10 to 13.5.
